(19) United States
(12) Patent Application Publication
(10) Pub. No.: US 2026/0370150 A1
(43) Pub. Date: Nov. 19, 2026

(54) OUTPUT VOLTAGE ESTIMATION FOR A POWER CONVERTER

(71) Applicant: POWER INTEGRATIONS, INC., San Jose, CA (US)

(72) Inventors: Karl Moore, Ely (GB); Antonius Jacobus Johannes Werner, Cambridge (GB)

(73) Assignee: POWER INTEGRATIONS, INC., San Jose, CA (US)

(21) Appl. No.: 19/408,078

(22) Filed: Dec. 3, 2025

Related U.S. Application Data
(60) Provisional application No. 63/805,166, filed on May 13, 2025.

(51) Int. Cl. H02M 3/335; G01R 19/00

(52) U.S. Cl. CPC H02M 3/33576; G01R 19/0084

(57) ABSTRACT

Systems and methods for output voltage estimation are described. In one embodiment, a method for controlling a power converter includes: determining a charge time T_{CHG} of a power switch; determining a discharge time T_{DIS} of the power switch; and determining an input voltage V_{IN} of an input side of an energy transfer element. The method further includes, in response to determining the charge time T_{CHG}, the discharge time T_{DIS}, and the input voltage V_{IN}, determining an output voltage sense signal VOS in response to the charge time T_{CHG}, the discharge time T_{DIS}, and the input voltage V_{IN}. The output voltage sense signal VOS is representative of an output voltage V_{O} at an output side of the energy transfer element. The method also includes providing the output voltage sense signal VOS to a control logic of a first controller.

### CROSS-REFERENCE(S) TO RELATED APPLICATION(S)

This application claims the benefit of U.S. Provisional Application No. 63/805,166, filed May 13, 2025, the disclosure of which is incorporated in its entirety by reference.

### BACKGROUND OF THE INVENTION

### Field of the Invention

The present disclosure relates generally to power converters, and more particularly, to controllers for power converters.

### Discussion of the Related Art

Electronic devices use power to operate. Switched mode power converters, also referred to as switching power converters, are commonly used to power many of today's electronics due to their high efficiency, small size and low weight. Conventional wall sockets provide a high voltage alternating current. In a switched mode power converter, a high voltage alternating current (ac) input is converted to provide a well-regulated direct current (dc) output through an energy transfer element. The switched mode power converter usually provides output regulation by sensing one or more signals representative of one or more output quantities and controlling the output in a closed loop. In operation, a switch is utilized to provide the desired output by varying the duty cycle (typically the ratio of the on time of the switch to the total switching period), varying the switching frequency, or varying the number of pulses per unit time of the switch in a switched mode power converter.

The output voltage is one example of an output quantity of the switched mode power converter. In addition to regulation, the output voltage may also be sensed for other purposes. For example, the output voltage may be sensed for fault conditions such as over voltage protection (OVP).

### SUMMARY OF THE DISCLOSURE

Isolated power converters generally have an input-side, also referred to as a primary-side, and an output side, also referred to as a secondary side, which are galvanically isolated from each other. Circuits coupled to the input-side of the power converter are referenced to an input return while circuits coupled to the output-side of the power converter are referenced to an output return. The input return and output return are also galvanically isolated. Since the input-side is galvanically isolated from the output-side, there is no direct (dc) current path across the isolation barrier of the power converter. Power converters may utilize energy transfer elements, with input windings and output windings, such as a transformer or coupled inductor to maintain the isolation.

A controller coupled to the input-side of the power converter generally has direct access to the input voltage V_{IN} of the power converter, while a controller coupled to the output-side of the power converter has direct access to the output voltage V_{O}. However, an input-side coupled power converter could have indirect access to the output voltage V_{O} due to energy transfer element. For example, a voltage across the input winding of an energy transfer element is the product of the energy transfer element turns ratio and the output voltage V_{O} when the power switch of the power converter is not conducting. The turns ratio and volt-second balance of an inductor provides a relationship between output voltage V_{O}, input voltage V_{IN}, reflected output voltage VOR, energy transfer element turns ratio, a charge time (T_{CHG}), and a discharge time (T_{DIS}). The charge time T_{CHG} may also be referred to as the power switch conduction time or the on-time of the power switch. The discharge time T_{DIS} may also be referred to as the output rectifier conduction time. Embodiments of the present disclosure measure the charge time T_{CHG} and discharge time T_{DIS} to estimate the output voltage V_{O} of the power converter. An input-side controller may therefore utilize the input winding voltage to determine the output voltage V_{O}. However, measuring the input winding voltage V_{IN} to determine the charge time T_{CHG} and discharge time T_{DIS} is difficult, because the input winding voltage V_{IN} may be too high for efficient and fast measurement by the input-side controller.

The power switch of the power converter may be in a cascode configuration comprising a normally-on switch, referred to as a first switch, and a normally-off switch, referred to as a second switch. Both the normally-on switch and the normally-off switch have intrinsic drain-source parasitic capacitances. When both the normally-on switch and the normally-off switch are OFF, the intrinsic capacitances of these switches may be used as a capacitive divider. As such, the voltage VDLV at the node between the normally-on switch and the normally-off switch is a scaled down replica of the input winding voltage V_{IN} when the power switch is OFF. Advantageously, measuring a relatively low voltage VDLV is easier executed by the input-side controller.

### BRIEF DESCRIPTION OF DRAWINGS

Non-limiting and non-exhaustive embodiments of the present invention are described with reference to the following figures, wherein like reference numerals refer to like parts throughout the various views unless otherwise specified.

Corresponding reference characters indicate corresponding components throughout the several views of the figures.

FIG. 1A illustrates an example power converter in accordance with the teachings of the present disclosure.

FIG. 1B illustrates another example power converter in accordance with the teachings of the present disclosure.

FIG. 2 illustrates a timing diagram 200 of various signals shown with respect to FIGS. 1A and 1B.

FIG. 3 illustrates a first controller 310, which is one example of first controller 110 shown in FIGS. 1A and 1B.

FIG. 4 illustrates a timing diagram 400 of various waveforms from FIG. 3.

### DETAILED DESCRIPTION

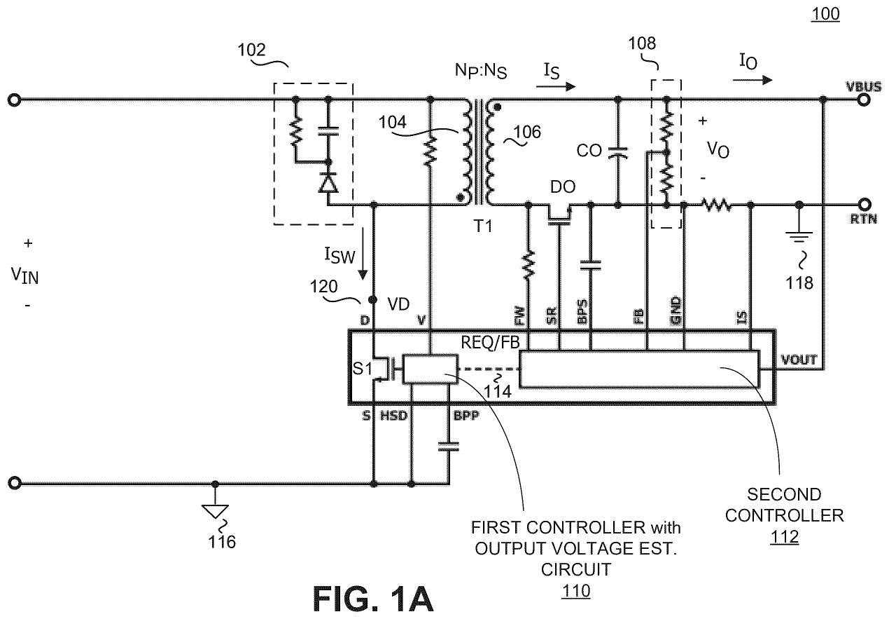

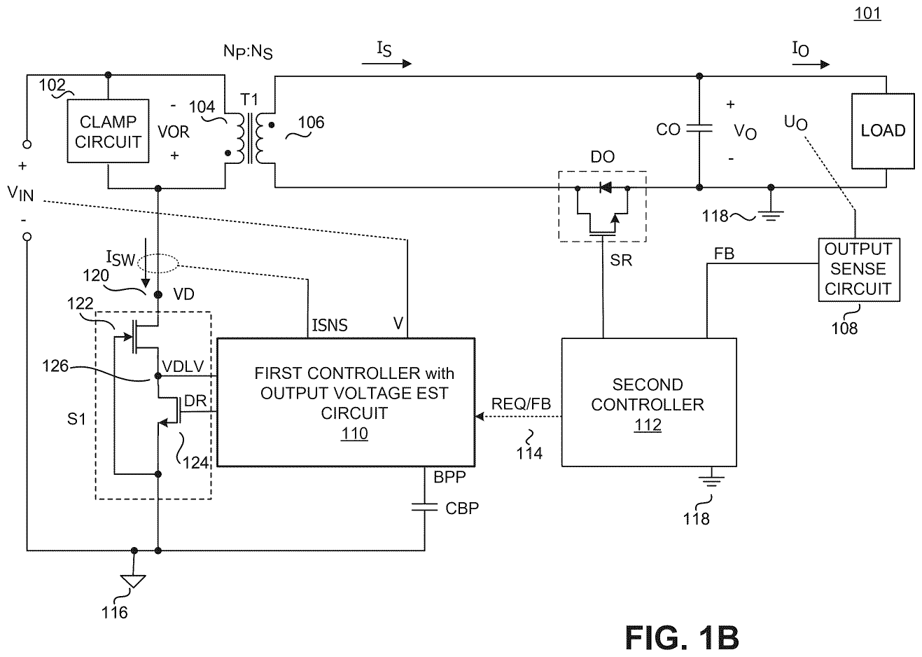

FIG. 1A shows an example power converter 100 which includes a first controller 110 (also referred to as an input side controller or a primary controller) with an output voltage estimation circuit and a second controller 112 (also referred to as an output side controller or a secondary controller) in accordance with an embodiment of the present disclosure. The power converter 100 further shows a clamp circuit 102, energy transfer element T1, an input winding 104 of the energy transfer element T1 with N_{P} number of turns, an output winding 106 of the energy transfer element T1 with N_{S} number of turns, a power switch S1, output rectifier DO, output capacitor CO, output sense circuit 108, input return 116, and output return 118. Also shown in FIG. 1A is an input voltage V_{IN}, switch current I_{SW} of the power switch S1, drain voltage VD of the power switch S1, output winding current I_{S}, output voltage V_{O}, output current I_{O}, a feedback signal FB representative of the output voltage V_{O}, and a request signal REQ representative of a request to turn ON the power switch S1. Power converter 100 is shown as having a flyback topology with the input galvanically isolated from the output. As such, input return 116 is galvanically isolated from output return 118. Clamp circuit 102 is coupled across input winding 104 and is shown as including a resistor, capacitor, and a diode. Clamp circuit 102 clamps the voltage across the input winding 104. Power switch S1 is coupled to the input winding 104.

Power switch S1 is exemplified as a transistor. The power switch S1 may be a transistor such as a metal-oxide semiconductor field-effect transistor (MOSFET), bipolar junction transistor (BJT), insulated-gate bipolar transistor (IGBT), gallium nitride (GaN) based transistor, silicon (Si) based, silicon carbide (SiC) based transistor, or other transistor. The power switch S1 may also be a cascode switch including a normally-on switch and a normally-off switch. An example of a cascode power switch S1 is shown in FIG. 1B.

In the embodiment of FIG. 1A, the first controller 110 is coupled to receive an input voltage sense signal V representative of the input voltage V_{IN} of the power converter. Although not shown, the first controller 110 may also receive a current sense signal ISNS representative of the switch current I_{SW}. The first controller 110 may receive a signal from the second controller 112 through a communication link 114. The communication link 114 may provide galvanic isolation, for example, through an inductive coupling such as a transformer or coupled inductor. Such transformer or coupled inductor may be formed from a lead frame. An optocoupler or a capacitive coupler may also provide galvanic isolation for the communication link 114.

The request signal REQ and the feedback signal FB are example signals which the first controller 110 may receive from the second controller 112. The first controller 110 outputs a drive signal DR to control the turn ON and turn OFF of the power switch S1. The switching of the power switch S1 controls the transfer of energy between the input-side and the output-side of the power converter 100. In one example operation, the first controller 110 outputs the drive signal DR to turn ON the power switch S1 in response to the request signal REQ 110. The first controller 100 outputs the drive signal DR to turn OFF the power switch S1 when the switch current I_{SW} reaches a current reference I_{CR}.

Output rectifier DO and the output capacitor CO are coupled to the output winding 106. Output rectifier DO is exemplified as a transistor coupled as a synchronous rectifier. The output rectifier DO may also be a diode. The voltage across output capacitor CO is the output voltage V_{O} of the power converter 100. Output sense circuit 108 is shown as a resistor divider coupled across the output capacitor. The feedback signal FB represents the scaled output voltage V_{O}.

The second controller 112 is coupled to receive the feedback signal FB. The second controller 112 outputs a second drive signal SR to control the turn ON and OFF of the output rectifier DO. In one example operation, the second controller 112 determines when to turn ON the power switch S1 in response to the feedback signal FB, which is representative of the output voltage V_{O}. The second controller 112 sends requests to turn ON the power switch S1 via the request signal REQ.

The first controller 110 (the input side controller) and the second controller 112 (the output side controller) form a control system for the power converter 100. The first controller 110 and the second controller 112 may be formed as part of an integrated circuit, which is manufactured as a hybrid or monolithic integrated circuit. The first controller 110 and second controller 112 may be formed as separate integrated circuits.

The power switch S1 may be formed as its own integrated circuit or formed in the same integrated circuit as the first controller 110. If the power switch S1 is a cascode, the power switch S1, first controller 110, and the second controller 112 may be housed in a single integrated circuit package, or may be implemented in separate packages, or a combination of combined/separate packages.

Node 120 represents a node of the input winding 104 with voltage VD. Node 120 is also the drain voltage of the power switch S1. The voltage VD at node 120 may be used to indirectly determine the output voltage V_{O} when the power switch S1 is off. The reflected output voltage VOR is the voltage across the input winding 104 when the power switch S1 is OFF and output rectifier DO is conducting. The voltage VD is substantially the sum of the reflected output voltage VOR and the input voltage V_{IN}, or, in mathematical terms: VD=V_{IN}+VOR.

Here, the reflected output voltage VOR is the product of the output voltage V_{O} and the turns ratio of the energy transfer element T1, or, in mathematical terms:

$$V OR = {V}_{O} \frac{{N}_{P}}{{N}_{S}} ,$$

where N_{P} is number of turns in the primary winding 104, and N_{S} is the number of turns in the secondary winding 106.

When the power switch S1 is ON, the on-time T_{ON}, also known as the charge time T_{CHG}, is substantially the product of the peak value PK of the switch current I_{SW} during the on-time T_{ON} and the inductance L_{P} of the input winding 104 divided by the input voltage V_{IN} during discontinuous conduction mode (DCM), or, in mathematical terms:

$${T}_{ON} = {T}_{CHG} = \frac{PK * {L}_{P}}{{V}_{IN}} .$$

When the output rectifier DO is conducting, the output rectifier conduction time, e.g., the discharge time T_{DIS}, is substantially the product of the peak value PK and the inductance L_{P} of the input winding 104 divided by the reflected output voltage VOR, or, in mathematical terms:

$${T}_{DIS} = \frac{PK * {L}_{P}}{V OR} .$$

Therefore, the ratio of the charge time T_{CHG} and the discharge time T_{DIS} is substantially the reflected output voltage VOR divided by the input voltage V_{IN}:

$$\frac{{T}_{CHG}}{{T}_{DIS}} = \frac{V OR}{{V}_{IN}} .$$

The reflected output voltage VOR may also be expressed as the product of the input voltage and the ratio of the charge time T_{CHG} and the discharge time T_{DIS} as:

$$V OR = {V}_{IN} \frac{{T}_{CHG}}{{T}_{DIS}} .$$

Generally, the first controller 110 can estimate the reflected output voltage VOR, and as such can estimate the output voltage V_{O}, by determining the charge time T_{CHG} and the discharge time T_{DIS}. The charge time T_{CHG} corresponds to the on-time T_{ON} of power switch S1. In one example, the charge time T_{CHG} may be determined from a signal which controls the turn ON and OFF of the power switch S1, such as the drive signal DR. In another example, the charge time T_{CHG} may be determined from the switch current I_{SW}.

The discharge time T_{DIS} may be determined from a signal which controls the turn ON and OFF of the power switch S1, such as the drive signal DR. The discharge time T_{DIS} may also be determined from a voltage representative of the input winding 104, such as the voltage VD. However, the discharge time T_{DIS} may also be determined from a mid-point voltage if the power switch S1 is a cascode switch. Such determination of the discharge time T_{DIS} may have some advantages because of lower magnitude of the voltage VDLV in comparison to the voltage VD, as discussed below.

FIG. 1B shows an example power converter 100 which includes the first controller 110 with an output voltage estimation circuit in accordance with an embodiment of the present disclosure. FIG. 1B is similar to FIG. 1A, and it should be appreciated that similarly named and numbered elements couple and function as described above. However, FIG. 1B illustrates the power switch S1 as a cascode power switch.

The illustrated power switch S1 is a cascode power switch with a first switch 122 and a second switch 124. The first switch 122 is a normally-on device and includes a drain terminal, source terminal, and a control terminal (e.g., gate terminal). The first switch 122 may be a high-voltage transistor. The first switch 122 may be a GaN based transistor. The first switch 122 is exemplified as a depletion mode GaN based transistor.

The second switch 124 is a normally-off device and includes a drain terminal, source terminal, and a control terminal (e.g., gate terminal). The second switch 124 may be a low-voltage transistor. In some embodiments, the second switch 124 may be a Si based transistor. The second switch 124 is exemplified as a MOSFET.

The control terminal of the first switch 122 is coupled to the source terminal of the second switch 124. The drain of the first switch 122 is the drain of the power switch S1. The source of the second switch 124 is the source of the power switch S1. Node 126 is shown as the node between the first switch 122 and the second switch 124. Node 126 is the source terminal of first switch 122 and the drain terminal of the second switch 124.

Voltage VDLV is the voltage at node 126, and is also the voltage of the drain of the second switch 124. Node 120 is the drain of power switch S1, and is also the drain of the first switch 122. Node 120 is also a terminal of the input winding 104. The voltage VD at node 120 is substantially the sum of input voltage V_{IN} and the reflected output voltage VOR when the power switch S1 is OFF (e.g., not conducting) while secondary rectifier DO is conducting. Furthermore, the voltage VD at node 120 is substantially zero when the power switch S1 is ON (e.g., conducting).

The first switch 122, the second switch 124, the first controller 110, and the second controller 112 may be formed as separate or in any combination of integrated circuits and/or packages with each other. In many embodiments, the first switch 122 and the second switch 124 have intrinsic drain-source parasitic capacitances. Therefore, when both the first switch 122 and the second switch 124 are in the OFF state, the intrinsic capacitances of these switches may be used as a capacitive divider. As such, the voltage VDLV at node 126 between the two switches 124 and 122 is a scaled replica of the input winding voltage VD when the power switch S1 is OFF. The scaling might be non-linear.

As mentioned above, the first controller 110 can estimate the reflected output voltage VOR, and as such can estimate the output voltage VO by determining the charge time T_{CHG} and the discharge time T_{DIS}. As explained above, the charge time T_{CHG} is equivalent to the on-time T_{ON} of power switch S1. In one example, the charge time T_{CHG} may be determined from a signal which controls the turn ON and OFF of the power switch S1, such as the drive signal DR. In another example, the charge time T_{CHG} may be determined from a signal which senses the switch current I_{SW}. Furthermore, the discharge time T_{DIS} may be determined from a signal which controls the turn ON and OFF of the power switch S1, such as the drive signal DR.

The discharge time T_{DIS} may also be determined from a voltage representative of the input winding 104, such as the voltage VD. As discussed above, the voltage VD may be too high for the first controller 110 to sense efficiently. However, the voltage VDLV is a scaled version of the voltage VD when the power switch S1 is OFF. Therefore, the voltage VDLV may also be utilized to determine the discharge time T_{DIS}. Other scaled versions of the voltage VD could be used to determine the discharge time T_{DIS}. For example, a resistor divider or a capacitive divider could be used to provide a scaled version of the voltage VD. The scaled version of VD may be used to determine the discharge time T_{DIS}.

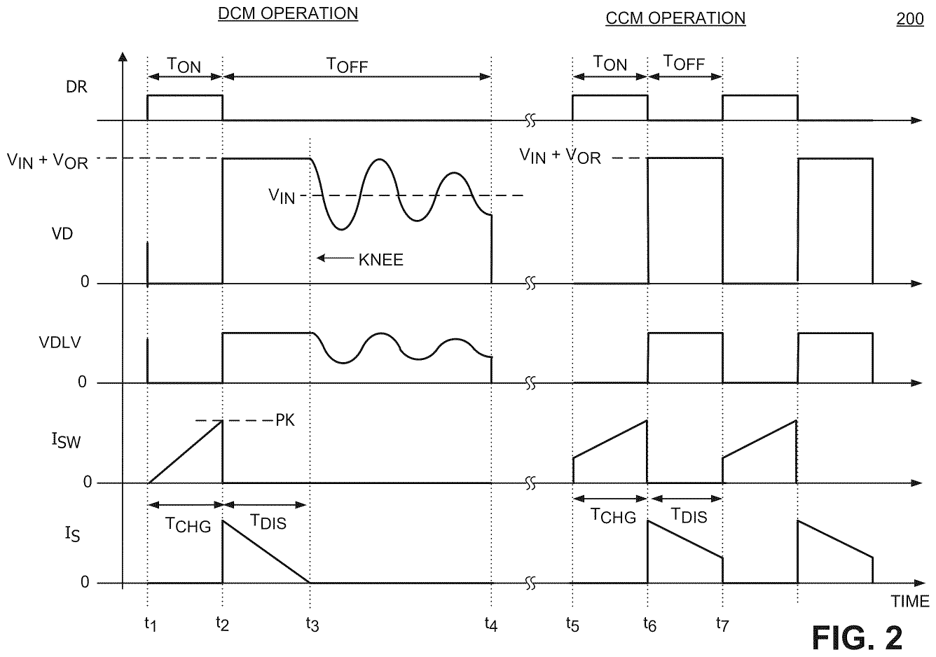

FIG. 2 illustrates a timing diagram 200 of various signals shown with respect to FIGS. 1A and 1B. In particular, FIG. 2 illustrates the drive signal DR, drain voltage VD of the cascode power switch S1, mid-point voltage VDLV of the cascode power switch S1, the switch current I_{SW}, and the output winding current I_{S}. The left side of the diagram illustrates the waveforms when the power converter is operating in discontinuous conduction mode (DCM). The right side of the diagram illustrates the waveforms when the power converter is operating in continuous conduction mode (CCM).

At time t1, the drive signal DR transitions to logic high value and the power switch S1 is controlled to the ON state and the second switch 124 is controlled ON. Generally, voltages VD and VDLV are substantially zero when the power switch S1 is conducting. For DCM, the switch current I_{SW} is substantially zero when the power switch S1 turns ON. As the power switch S1 is conducting, the switch current I_{SW} increases. The rate of increase of the I_{SW} is a function of the inductance LP of the input winding 102 and the input voltage V_{IN}. The shape of the switch current I_{SW} is substantially triangular for DCM. The output winding current I_{S} is substantially zero when the power switch S1 is ON. The switch current I_{SW} reaches a peak value PK when the power switch S1 is turned OFF at time t2. The duration between time t1 and time t2 is substantially the on-time Ton of power switch S1. The duration between time t1 and time t2 is also substantially the charge time T_{CHG}.

At time t2, the drive signal DR transitions to a logic low value and the power switch S1 is controlled OFF. For a cascode power switch S1, the second switch 124 is controlled to OFF state. Voltage VD substantially increases to the sum of the input voltage V_{IN} and the reflected output voltage VOR. The voltage VDLV also increases to a scaled sum of the input voltage V_{IN} and the reflected output voltage VOR. As explained above, the scaling factor between voltages VD and VDLV is responsive to the intrinsic capacitances of the first switch 122 and second switch 124. Once the power switch S1 is turned off at time t2, the output rectifier DO begins to conduct, and there is non-zero output winding current I_{S}.

At time t3, the output winding current I_{S} reaches substantially zero. This indicates that all the energy in the windings has been transferred from the input-side to the output-side of the power converter. The shape of the output winding current I_{S} is substantially triangular.

A relaxation ring can be observed in both voltages VD and VDLV after time t3. The reduction in voltages VD and VDLV at time t3 is often referred to as the “knee point.” In other words, the knee point may also refer to the start of the relaxation ring in voltages VD and VDLV. The knee point may also be determined from a sudden change in slope in either voltages VD or VDLV, a sudden change in either voltages VD or VDLV, or an end of a plateau in either voltages VD or VDLV. The duration between time t2 and time t3 is substantially the discharge time T_{DIS}. Time t4 is shown as the end of the off-time T_{OFF} of the power switch S1.

The waveforms shown from time t5 onward are similar as discussed above, however the power converter is operating in CCM. At least some of the differences are discussed below. At time t5, the drive signal DR transitions to logic high value and the power switch S1 is controlled ON. In response, the switch current I_{SW} increases. However, for the CCM operation, the switch current I_{SW} is substantially non-zero when the power switch S1 turns ON. As such, the shape of switch current I_{SW} is substantially trapezoidal.

At time t6, the drive signal DR transitions to logic low value and the power switch S1 is controlled to OFF state. Voltages VD substantially increases to the sum of the input voltage V_{IN} and the reflected output voltage VOR. The voltage VDLV also increases to a scaled sum of the input voltage V_{IN} and the reflected output voltage VOR. As seen in the graph, the duration between time t5 and time t6 is substantially the on-time T_{ON} of the power switch S1. The duration between time t5 and time t6 is also substantially the charge time T_{CHG}. Furthermore, the output rectifier DO begins to conduct, and there is non-zero output winding current IS.

At time t7, the drive signal DR transitions to logic high value and the power switch S1 is controlled ON. However, at time t7, the output winding current I_{S} is still substantially non-zero. As such, the shape of output winding current I_{S} is substantially trapezoidal, thus indicating that not all the energy has been transferred from the input-side to the output-side of the power converter. The duration between time t6 and time t7 is substantially the discharge time T_{DIS}.

The first controller 110 may estimate the output voltage VO by determining the charge time T_{CHG} and discharge time T_{DIS}. The charge time T_{CHG} may be measured from a signal representative of the control of the power switch S1, such as the drive signal DR, for both DCM and CCM operation. The discharge time T_{DIS} can also be measured from a signal representative of the control of the power switch S1, such as the drive signal DR during CCM. During DCM, the first controller 110 detects the knee point in voltage VDLV to determine the discharge time T_{DIS}.

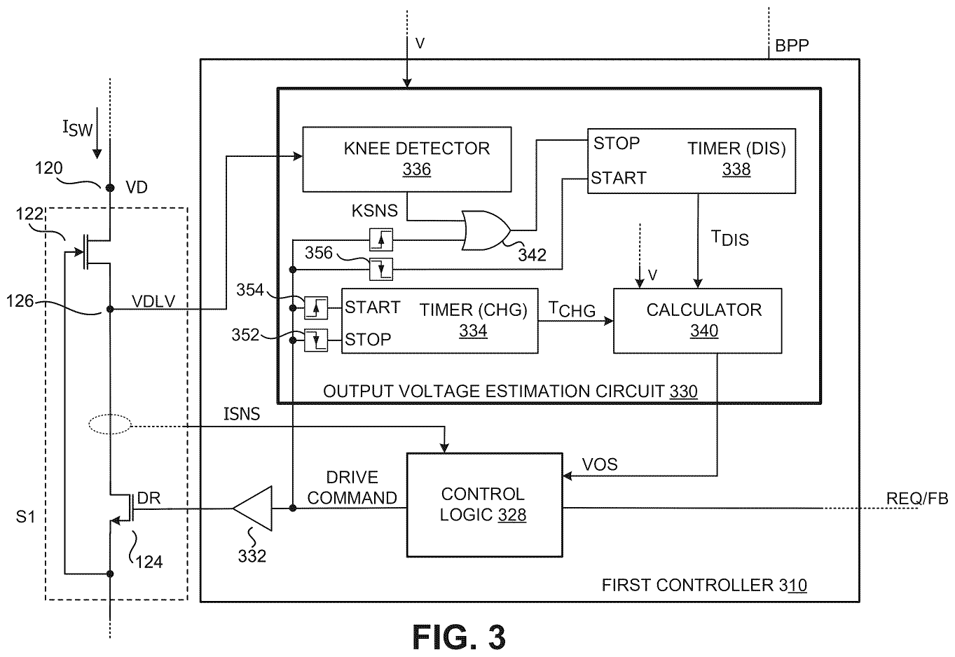

FIG. 3 illustrates a first controller 310, which is one example of first controller 110 shown in FIGS. 1A and 1B. The cascode power switch S1 with first switch 122 and second switch 124 of FIG. 1B is illustrated for context, but the inventive technology may apply to other controller architectures. First controller 310 is shown as including control logic 328, output voltage estimation circuit 330 and driver 332. Control logic 328 is coupled to receive either the request signal REQ or feedback signal FB. Furthermore, control logic 328 outputs a drive command signal DRIVE COMMAND representative of turn ON and turn OFF commands for the power switch S1. In some embodiments, drive command signal DRIVE COMMAND is a rectangular pulse waveform with varying durations of on-sections and off-sections. On-sections are representative of a turn ON command for the power switch S1 and off-sections are representative of a turn OFF command of the power switch S1.

Control logic 328 is also coupled to receive the current sense signal ISNS representative of switch current I_{SW}. In one example operation, the control logic 328 outputs the drive command signal DRIVE COMMAND to turn ON the power switch S1 in response to a request by the request signal REQ. The control logic 328 outputs the drive command signal DRIVE COMMAND to turn OFF the power switch S1 in response to the switch current I_{SW} reaching a current reference.

Driver 332 receives the drive command signal DRIVE COMMAND and outputs the drive signal DR. In different embodiments, the drive signal DR may be a voltage signal or a current signal. The drive signal DR may be a rectangular pulse waveform with varying durations of on-sections and off-sections. During an on-section, the drive signal DR is substantially a voltage value or current value to turn ON and maintain ON the power switch S1. During an off section, the drive signal DR is substantially a voltage value or a current value to turn OFF and maintain OFF the power switch S1. In operation, the driver 332 converts the turn ON and turn OFF commands of the drive command signal DRIVE COMMAND to the voltage or current values to turn ON or turn OFF the particular device used for the power switch S1. For the example shown, the driver 332 converts the turn ON and turn OFF commands of the drive command signal DRIVE COMMAND to the voltage value to turn ON and OFF the second switch 124.

An output voltage estimation circuit 330 is coupled to receive the mid-point voltage VDLV at node 126 and the input voltage sense signal V representative of input voltage V_{IN}. The output voltage estimation circuit 330 also receives a signal representative of the control of the power switch S1. As shown, the output voltage estimation circuit 330 receives the DRIVE COMMAND signal, which is a signal representative of the control of the power switch S1. The drive signal DR is also a signal representative of the control of the power switch S1. Therefore, the output voltage estimation circuit 330 may alternatively receive the drive signal DR.

The output voltage estimation circuit 330 is configured to provide the output voltage sense signal VOS, representative of the output voltage V_{O} of the power converter. Control logic 328 receives the output voltage sense signal VOS. In one example operation, controller logic 328 may implement auto-restart or latch off in response to the output voltage sense signal VOS. Output voltage estimation circuit 330 includes timer 334 (also referred to as a first timer), knee detector 336, timer 338 (also referred to as a second timer), calculator 340 and OR gate 342.

A timer 334 is utilized to measure the charge time T_{CHG}. The timer 334 receives the drive command signal. In response to the drive command signal, the timer 334 starts and stops timing. The timer 334 starts timing when the drive command signal indicates that the power switch S1 is to be turned ON and stops timing when the drive command signal indicates that the power switch S1 is to be turned OFF. In one example response, timer 334 starts timing at a leading edge of the drive command signal and stops timing at a trailing edge of the drive command signal. An output of the timer 334 is a signal representative of the charge time T_{CHG}. In FIG. 3, a rising edge detection block 354 and a falling edge detection block 352 are shown to illustrate that timer 334 is responsive to the leading and falling edge of the drive command signal. Example rising and falling edge detection blocks may include latches or flip-flops.

A knee detector 336 is coupled to receive a scaled version of the drain voltage VD and determine the knee point. In the example shown, knee detector 336 is coupled to receive the voltage VDLV and determines the knee point in VDLV. In other embodiments, the knee detector 336 could receive a scaled down version of the drain voltage VD from the output of a resister divider or a capacitor divider. The knee detector 336 outputs knee sense signal KSNS representative of the sensed knee point in voltage VDLV. In one embodiment, the knee detector may compare voltage VDLV to a delayed version of voltage VDLV to find the knee point. In another embodiment, the knee detector may periodically sample voltage VDLV and compare the difference between adjacent samples to find the knee point. In the example shown, an OR gate 342 is coupled to receive the knee point sense signal as one input and the drive command signal at another input.

It should be appreciated that the knee detector 336 may be coupled to receive the drain voltage VD and determines the knee point in drain voltage VD. The knee detector 336 would then output the knee sense signal KSNS representative of the sensed knee point in drain voltage VD.

A timer 338 is utilized to measure the discharge time T_{DIS}. In operation, the timer 338 receives and responds to the drive command signal. The timer 338 starts timing when the drive command signal indicates that the power switch S1 is to be turned OFF. The timer 338 stops timing when the knee sense signal KSNS indicates that the “knee point” in VDLV has been sensed or the drive command signal indicates to turn ON the power switch S1, whichever is sooner. Therefore, an output of the timer 338 is a signal representative of the discharge time T_{DIS}. For the example shown, the timer 338 starts timing in response to a trailing edge of the drive command signal, and stops timing in response to the output of OR gate 342. The falling edge block 356 is shown to illustrate that the timer 338 responds to the falling edge of the drive command signal.

A calculator 340 is coupled to receive the input voltage sense signal V and the signals representative of the charge time T_{CHG} and discharge time T_{DIS}. The calculator is configured to estimate the reflected output voltage and outputs the result as the output voltage sense signal VOS. As discussed above, the reflected output voltage VOR is the product of the input voltage V_{IN}, which is represented by input voltage sense signal V, and the ratio between the charge time T_{CHG} and discharge time T_{DIS}. Expressed mathematically, the calculator determines

$$V OR = {V}_{IN} \frac{{T}_{CHG}}{{T}_{DIS}} .$$

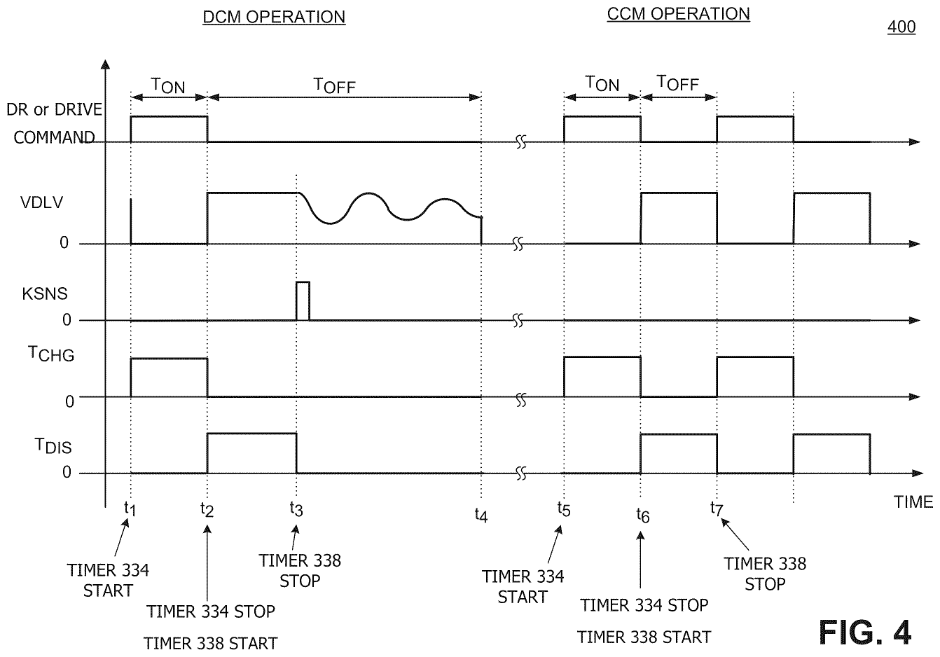

FIG. 4 illustrates a timing diagram 400 of various signals from FIG. 3. In particular, FIG. 4 illustrates examples of the drive signal or drive command signal, voltage V_{DLV}, knee sense signal KSNS, the signal representative of charge time T_{CHG} and the signal representative of discharge time T_{DIS}. Similar to the graphs shown in FIG. 2, the left side of the diagram illustrates the waveforms when the power converter is operating in discontinuous conduction mode (DCM), while the right side of the diagram illustrates the waveforms when the power converter is operating in continuous conduction mode (CCM).

As explained above, at time t1, the drive signal DR transitions to logic high value and the power switch S1 is controlled to the ON state and the second switch 124 is controlled ON. In response, voltage VDLV becomes substantially zero when the power switch S1 is conducting. Transitioning the drive signal DR to the logic high value also marks a beginning of the T_{ON} period for the drive signal DR. Based on the drive signal DR transitioning to logic high value, the timer 334 begins determination of the charge time T_{CHG}.

At time t2, the drive signal DR transitions to a logic low value and the power switch S1 is controlled to the OFF state. In response, the voltage VDLV increases to a scaled sum of the input voltage VIN and the reflected output voltage VOR. As explained above, the scaling factor is responsive to the intrinsic capacitances of the first switch 122 and second switch 124. The timer 334 begins timing at time t1 and the signal representative of the charge time T_{CHG} transitions to a logic high value. Switching of the power switch S1 to the OFF state ends the T_{ON} time of power switch S1. The timer 334 stops timing and the timer 334 determines a duration of the T_{CHG} time. As shown, the signal representative of the charge time T_{CHG} transitions to a logic high value at time t2. At time t2, the timer 338 starts determination of the T_{DIS} time. The signal representative of the discharge signal T_{DIS} transitions to a logic high value at time t2.

At time t3, the output winding current IS reaches substantially zero. As explained above, this indicates that all the energy in the windings has been transferred from the input-side to the output-side of the power converter, and a relaxation ring can be observed in VDLV after time t3 for DCM operation. The duration between time t2 and time t3 is substantially the discharge time T_{DIS}. At time t3, the knee detector 336 outputs knee sense signal KSNS (e.g., a pulse) representative of the sensed knee point in voltage VDLV. The knee sense signal KSNS also signifies the end of the discharge time T_{DIS} as determined by the timer 338. The timer 338 stops timing, and the signal representative of the discharge time T_{DIS} transitions to a logic low value at time t3. At this point, both the T_{CHG} and T_{DIS} times are determined by the timers 334 and 338, and the calculator 340 can determine the output voltage sense signal VOS and provide this signal to the control logic 328. Since the voltage sense signal VOS is representative of the output voltage V_{O} of the power converter, the control logic 328 can determine whether a new drive command DR should be sent to the cascode switch. Time t4 is shown as the end of the off-time TOFF of the power switch S1.

The waveforms shown from time t5 onward are similar as discussed above, however the power converter is operating in CCM, therefore the switch current I_{SW} is substantially non-zero when the power switch S1 turns ON. At time t5, the power switch S1 is turned ON and the signal representative of the charge time t_{CHG} transitions to a logic high value, indicating that the timer 334 is timing. At time t6, the power switch S1 is controlled OFF and the timer 334 stops timing and the timer 334 determines a duration of the T_{CHG} time. The timer 338 starts determination of the T_{DIS} time and the signal representative of the discharge signal T_{DIS} transitions to a logic high value at time t6. For CCM operation, the end of the discharge time T_{DIS} is determined by the drive command signal and/or the drive signal controlling the power switch S1 to the OFF state. The timer 338 is configured to determine duration of the T_{DIS} period from the drive command signal and/or the drive signal. At time t7, the power switch s1 is controlled OFF and the signal representative of the discharge time T_{DIS} transitions to a logic low state. At time t7 both the T_{CHG} and T_{DIS} times are determined, and the calculator 340 can determine the voltage sense signal VOS. Based on the voltage sense signal VOS, which is representative of the output voltage V_{O} of the power converter, the control logic 328 can determine whether a new drive command DR should be sent to the cascode switch, similar to the process explained with respect to the DCM operation above.

Numerous specific details are set forth above in order to provide a thorough understanding of the present invention. It will be apparent, however, to one having ordinary skill in the art that the specific detail need not be employed to practice the present invention. In other instances, well-known materials or methods have not been described in detail in order to avoid obscuring the present invention. For example, skilled artisans will appreciate that elements in the previously described figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in the figures in order to facilitate a less obstructed view of these various embodiments of the present invention.

Reference throughout this specification to “one embodiment”, “an embodiment”, “one example” or “an example” means that a particular feature, structure or characteristic described in connection with the embodiment or example is included in at least one embodiment of the present invention. Thus, appearances of the phrases “in one embodiment”, “in an embodiment”, “one example” or “an example” in various places throughout this specification are not necessarily all referring to the same embodiment or example. Furthermore, the particular features, structures or characteristics may be combined in any suitable combinations and/or subcombinations in one or more embodiments or examples. Particular features, structures or characteristics may be included in an integrated circuit, an electronic circuit, a combinational logic circuit, or other suitable components that provide the described functionality.

The description of illustrated examples of the present invention, including what is described in the Abstract, are not intended to be exhaustive or to be a limitation to the precise forms disclosed. While specific embodiments of, and examples for, the invention are described herein for illustrative purposes, various equivalent modifications are possible without departing from the broader spirit and scope of the present invention. Indeed, it is appreciated that any specific example voltages, currents, frequencies, power range values, times, etc., are provided for explanation purposes and that other values may also be employed in other embodiments and examples in accordance with the teachings of the present invention.

What is claimed is:

1. A method for controlling a power converter, the method comprising:
determining a charge time T_{CHG} of the power converter;
determining a discharge time T_{DIS} of the power converter;
determining an input voltage V_{IN} of an input side of an energy transfer element;
determining an output voltage sense signal VOS in response to the charge time T_{CHG}, the discharge time T_{DIS}, and the input voltage V_{IN}, wherein the output voltage sense signal VOS is representative of an output voltage V_{O} at an output side of the energy transfer element; and
providing the output voltage sense signal VOS to a control logic of a first controller.

2. The method of claim 1, wherein the charge time T_{CHG} is determined as an on-time T_{ON} of the power switch.

3. The method of claim 2, wherein the charge time T_{CHG} is determined from a signal representative of control of the power switch.

4. The method of claim 1, wherein determining the discharge time T_{DIS} is based on detecting a knee point in a drain voltage VD of the power switch or a scaled down version of the drain voltage VD.

5. The method of claim 4, wherein the scaled down version of the drain voltage VD is from a voltage VDLV at a node of the power switch located between a first switch and a second switch of the power switch.

6. The method of claim 5, wherein scaling down of the drain voltage VD of the power switch is based on intrinsic drain-source parasitic capacitances of the first switch and the second switch of the power switch.

7. The method of claim 4, wherein detection of the knee point signifies ending of the discharge time T_{DIS} of the power switch.

8. The method of claim 1, wherein determining the discharge time T_{DIS} is based on determining an off-time T_{OFF} of the power switch.

9. The method of claim 8, wherein the discharge time T_{DIS} is determined from a signal representative of control of the power switch.

10. The method of claim 1, further comprising generating a drive command by the control logic of the first controller, wherein the drive command controls the second switch of the power switch to ON or OFF state.

11. A control system for use in a power converter, comprising:
a first controller configured to control a power switch, wherein the power switch comprises a first switch and a second switch coupled in a cascode configuration, the first controller comprising:
an output voltage estimation circuit configured to determine an output voltage sense signal VOS, wherein the output voltage sense signal VOS is representative of an output voltage V_{O} at the output side of an energy transfer element, and wherein the output voltage estimation circuit is further configured for:
determining a charge time T_{CHG} of the power converter;
determining a discharge time T_{DIS} of the power converter;
determining an input voltage V_{IN} of an input side of an energy transfer element;
in response to determining the charge time T_{CHG}, discharge time T_{DIS}, and input voltage V_{IN}, determining the output voltage sense signal; and
providing the output voltage sense signal VOS to a control logic of the first controller.

12. The system of claim 11, wherein the output voltage estimation circuit comprises a first timer configured to determine the charge time T_{CHG} as an on-time T_{ON} of the power switch.

13. The system of claim 12, wherein the charge time T_{CHG} is determined from a signal representative of control of the power switch.

14. The system of claim 11, wherein the output voltage estimation circuit comprises a knee detector configured for detecting a knee point in a drain voltage of the power switch or a scaled down version of the drain voltage VD.

15. The system of claim 14, wherein the scaled down version of the drain voltage VD is from a voltage VDLV at a node of the power switch located between a first switch and a second switch of the power switch.

16. The system of claim 15, wherein the output voltage estimation circuit comprises a second timer configured to determine the discharge time T_{DIS}, based on the knee point in the node of the power switch.

17. The system of claim 15, wherein scaling down of the drain voltage VD of the power switch is based on an intrinsic drain-source parasitic capacitances of the first switch and the second switch of the power switch.

18. The system of claim 14, wherein detection of the knee point signifies ending of the discharge time T_{DIS}.

19. The system of claim 11, wherein determining the discharge time T_{DIS} is based on determining an off-time T_{OFF} of the power switch.

20. The system of claim 19, wherein the discharge time T_{DIS} is determined from a signal representative of control of the power switch.

21. The system of claim 11, further comprising generating a drive command by the control logic of the first controller, wherein the drive command controls the second switch of the power switch to ON or OFF state.

22. A controller configured to control a power switch of a power converter to control the transfer of energy between an input-side and an output-side of the power converter, the controller comprising:
a control logic configured to provide a signal to control the power switch, wherein the power switch comprises a first switch and a second switch coupled in a cascode configuration; and
an output voltage estimation circuit configured to receive an input voltage sense signal V representative of input voltage V_{IN} and to determine a charge time T_{CHG} and a discharge time T_{DIS} of the power converter, wherein the output voltage estimation circuit is further configured to provide an output voltage sense signal VOS representative of an output of the power converter in response to the input voltage sense signal V, the charge time T_{CHG}, and the discharge time VOS.

23. The controller of claim 22, wherein the output voltage estimation circuit comprises a first timer configured to determine the charge time T_{CHG} as an on-time T_{ON} of the power switch.

24. The controller of claim 23, wherein the charge time T_{CHG} is determined from a signal representative of control of the power switch.

25. The controller of claim 22, wherein the output voltage estimation circuit comprises a knee detector configured for detecting a knee point in a drain voltage VD of the power switch or a scaled down version of a drain voltage VD.

26. The controller of claim 25, wherein the scaled down version of the drain voltage VD is from a voltage VDLV at a node of the power switch located between a first switch and a second switch of the power switch.

27. The controller of claim 26, wherein the output voltage estimation circuit comprises a second timer configured to determine the discharge time T_{DIS}, based on the knee point in the node of the power switch.

28. The controller of claim 26, wherein scaling down of the drain voltage VD of the power switch is based on an intrinsic drain-source parasitic capacitances of the first switch and the second switch of the power switch.

29. The controller of claim 25, wherein detection of the knee point signifies ending of the discharge time T_{DIS}.

30. The controller of claim 22, wherein determining the discharge time T_{DIS} is based on determining an off-time T_{OFF} of the power switch.

31. The controller of claim 30, wherein the discharge time T_{DIS} is determined from a signal representative of control of the power switch.

32. The controller of claim 22, further comprising generating a drive command by the control logic of the first controller, wherein the drive command controls the second switch of the power switch to ON or OFF state.
